(19) United States
(12) Patent Application Publication
(10) Pub. No.: US 2024/0355851 A1
(43) Pub. Date: Oct. 24, 2024

(54) PHOTOELECTRIC SENSOR AND FABRICATION METHOD THEREOF, AND ELECTRONIC DEVICE

(71) Applicants: Semiconductor Manufacturing International (Shanghai) Corporation, Shanghai (CN); Semiconductor Manufacturing International (Beijing) Corporation, Beijing (CN)

(72) Inventors: Hongmin LIU, Beijing (CN); Xinpeng WANG, Beijing (CN); Qiangwei CUI, Beijing (CN); Guilin FAN, Beijing (CN)

(21) Appl. No.: 18/579,817

(22) PCT Filed: Jul. 30, 2021
(86) PCT No.: PCT/CN2021/109682

§ 371 Date: Jan. 16, 2024

(51) Int. Cl. H01L 27/146

(52) U.S. Cl. CPC H01L 27/14625; H01L 27/14607; H01L 27/14685

(57) ABSTRACT

A photoelectric sensor includes: a substrate with a light-receiving surface. The substrate includes a photosensitive pixel area and the photosensitive pixel area includes pixel unit areas distributed in a matrix. Light traps are located in a part of a thickness of the substrate in the pixel unit area. The light traps are located on the light-receiving surface of the substrate, and distributed in a matrix along a row direction and a column direction. The row direction is perpendicular to the column direction. Adjacent light traps in the column direction are connected, and adjacent light traps in the row direction are connected. Side walls of the plurality of light traps surround and form a plurality of protrusions. Adjacent protrusions are connected, and the plurality of protrusions has a shape of octagonal pyramid.

### TECHNICAL FIELD

The present disclosure generally relates to the field of semiconductor fabrication technology and, more particularly, relates to a photoelectric sensor and its fabrication method, and an electronic device.

### BACKGROUND

A photoelectric sensor is a device that converts optical signals into electrical signals. Its working principle is based on the photoelectric effect. The photoelectric effect means that when light shines on certain substances, electrons of the substances absorb the energy of the photons and a corresponding electrical effect occurs.

For example, charge coupled device (CCD) image sensors and CMOS image sensors use photoelectric conversion functions to convert optical images into electrical signals and then output digital images, and are currently widely used in digital cameras and other optoelectronic devices. A time of flight (TOF) distance sensor projects a modulated infrared light source onto an object, person or scene, and then the reflected light is captured by a TOF sensor. The sensor measures the light intensity and phase difference received by each pixel to obtain highly reliable depth images and grayscale images of the entire scene. This technology can be used in various ranging scenarios such as autonomous driving, sweeping robots, virtual reality (VR)/augmented reality (AR) modeling, etc.

A photoelectric sensor usually has a pixel region of a certain area, which is used to receive optical signals. When the optical transmittance of the pixel region is higher, the optical sensitivity performance of the device is better.

However, the photosensitive performance of existing photoelectric sensors needs to be improved.

### Technical Problems

The preset disclosure provides a photoelectric sensor and its fabrication method, and an electronic device, to improve the photosensitive performance of the photoelectric sensor.

### SUMMARY

To solve the above technical problems, the present disclosure provides a photoelectric sensor. The photoelectric sensor includes: a substrate with a light-receiving surface, where the substrate includes a photosensitive pixel area and the photosensitive pixel area includes a plurality of pixel unit areas distributed in a matrix; and a plurality of light traps located in a part of a thickness of the substrate in the plurality of pixel unit area. The plurality of light traps is located on the light-receiving surface of the substrate, and distributed in a matrix along a row direction and a column direction. The row direction and the column direction are perpendicular. Adjacent light traps in the column direction are connected, and adjacent light traps in the row direction are connected. Side walls of the plurality of light traps surround and form a plurality of protrusions. Adjacent protrusions are connected, and the plurality of protrusions has a shape of an octagonal pyramid. In the plurality of pixel unit areas, the eight sides and the top surfaces of each protrusion can be used as photosensitive surfaces of the photoelectric sensor.

Another aspect of the present disclosure also provides a fabrication method of a photoelectric sensor. The method includes: providing a substrate including a photosensitive pixel area and the photosensitive pixel including a plurality of pixel unit areas distributed in a matrix; forming a plurality of discrete first grooves in the light-receiving surface of the substrate in the plurality of pixel unit areas; forming a protective layer on the side walls of the plurality of first grooves; after forming the protective layer, removing a portion of a thickness of the substrate exposed by the plurality of first grooves, to form second grooves connected to the plurality of first grooves, where side walls of the second grooves are perpendicular to the <100> crystal direction, and the plurality of first grooves and the second grooves form initial light traps; and using a wet etching process to etch the substrate exposed by the second grooves, such that the initial light traps are connected along the row direction and the column direction respectively to form light traps and protrusions surrounded by side walls of the light traps. The substrate has a cubic crystal structure. A material lattice of the substrate includes a {100} crystal plane family, a {110} crystal plane family and a {111} crystal plane family; and a light-receiving surface of the substrate is the {100} crystal plane or the {110} crystal plane. The plurality of first grooves is square grooves or circular grooves. Side walls of plurality of first grooves are perpendicular to the <100> crystal direction, the plurality of first grooves is arranged in a matrix along a row direction and a column direction; and the row direction and the column direction are perpendicular. Adjacent protrusions are connected. The plurality of protrusions has a shape of an octagonal pyramid. Among the etching rates of the various crystal planes of the substrate in the wet etching process, the etching rate of the {100} crystal plane is the largest, and the etching rate of the {111} crystal plane is the smallest.

Another aspect of the present disclosure also provides an electronic device including a photoelectric sensor provided by the present disclosure.

### Effective Benefits

Compared to existing technologies, the present disclosure has following benefits. In the photoelectric sensor provided by the present disclosure, the plurality of light traps is distributed in a matrix along a row direction and a column direction. The row direction and the column direction are perpendicular. Adjacent light traps in the column direction are connected, and adjacent light traps in the row direction are connected. Side walls of the plurality of light traps surround and form a plurality of protrusions. Adjacent protrusions are connected, and the plurality of protrusions has a shape of an octagonal pyramid. In the plurality of pixel unit areas, the eight sides and the top surfaces of each protrusion can be used as photosensitive surfaces of the photoelectric sensor. Compared with the light trap with an inverted pyramid structure or a rectangle structure of the photoelectric sensor, the embodiments of the present disclosure may significantly increase the photosensitive area of the photoelectric sensor, and increase the number of reflections of incident light between the photosensitive surfaces. At the same time, the optical path difference of the incident light may be also increased, improving the light localization capability of the photoelectric sensor. The photosensitive performance of the photoelectric sensor may be improved.

In the fabrication method of the photoelectric sensor provided by the present disclosure, a material of a substrate may belong to a cubic crystal system. In the material of the substrate, crystal planes and crystal directions of the same index are perpendicular to each other. In the present disclosure, the light-receiving surface may be a {100} crystal plane or a {110} crystal plane. Side walls of the first grooves may be perpendicular to the <100> crystal direction, and side walls of the corresponding second grooves may be also perpendicular to the <100> crystal direction. Among the etching rates of each crystal plane in the wet etching process, the etching rate for the {100} crystal plane may be the largest, and the etching rate for the {111} crystal plane may be the smallest. That is, the wet etching process may have the highest etching rate along the <100> crystal direction, and the smallest etching rate along the <111> crystal direction. Since a protective layer may be formed on the side walls of the first grooves, the side walls of the second groove may be etched before the side walls of the first grooves. In the process of etching the substrate exposed by the second grooves, the completed surface obtained by etching may gradually approach the {111} crystal plane, that is, the side walls of the second grooves may gradually become four {111} crystal planes. After the second grooves expose the {111} crystal planes, as the etching continues, the second grooves may expose the side walls of the first grooves. The sidewalls of the first grooves may be perpendicular to the <100> crystallographic direction. Therefore, the etching rate of the substrate at the exposed side walls of the first grooves may be accelerated, while the etching rate of the substrate of the {111} crystal plane exposed by the second grooves may be still slow. Because of the difference in etching rates between the two places, each {111} crystal plane may be etched to form two faces. Correspondingly, the aforementioned four {111} crystal planes may be etched to totally form eight faces. Therefore, after the initial light traps are connected in the row direction and the column direction to form the light traps, the shape of the protrusions surrounded by side walls of the light traps may be an eight-sided pyramid. In a pixel unit area, the eight sides and the top surface of each protrusion may be used as the photosensitive surface of the light sensor. Compared with the light trap with an inverted pyramid structure or a rectangle structure of the photoelectric sensor, the embodiments of the present disclosure may significantly increase the photosensitive area of the photoelectric sensor, and increase the number of reflections of incident light between the photosensitive surfaces. At the same time, the optical path difference of the incident light may be also increased, improving the light localization capability of the photoelectric sensor. The photosensitive performance of the photoelectric sensor may be improved.

### BRIEF DESCRIPTION OF THE DRAWINGS

FIG. 1 to FIG. 4 illustrate structures corresponding to certain stages of a fabrication method of a photoelectric sensor.

FIG. 5 to FIG. 8 illustrate structures of a photoelectric sensor according to various disclosed embodiments of the present disclosure.

FIG. 9 to FIG. 26 illustrate structures corresponding to certain stages of a fabrication method of a photoelectric sensor according to various disclosed embodiments of the present disclosure.

### DETAILED DESCRIPTION

As described in the background, the photosensitive performance of current photoelectric sensors still needs to be improved.

The reasons of the poor photosensitive performance of current photoelectric sensors will be analyzed and described below in combination with a fabrication method of a photoelectric sensor.

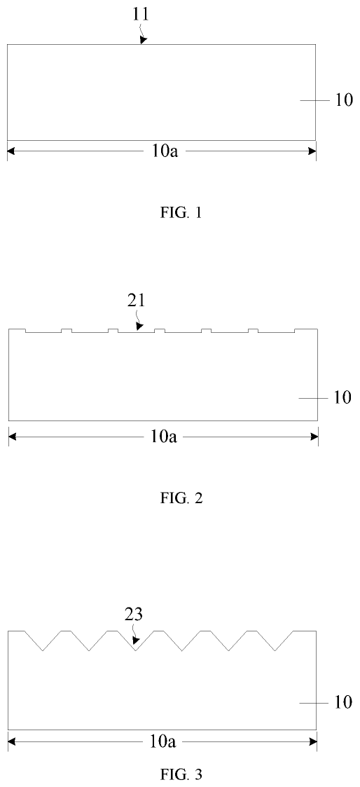

FIG. 1 to FIG. 4 illustrate structures corresponding to certain stages of a fabrication method of a photoelectric sensor.

As shown in FIG. 1, a substrate 10 is provided. The substrate 10 has a light-receiving surface 11. The substrate 10 includes a pixel area (not shown), and the pixel area includes a plurality of pixel unit areas 10a distributed in a matrix.

As shown in FIG. 2, in one pixel unit area 10a, a plurality of discrete grooves 21 are formed in the light-receiving surface 11 of the substrate 10.

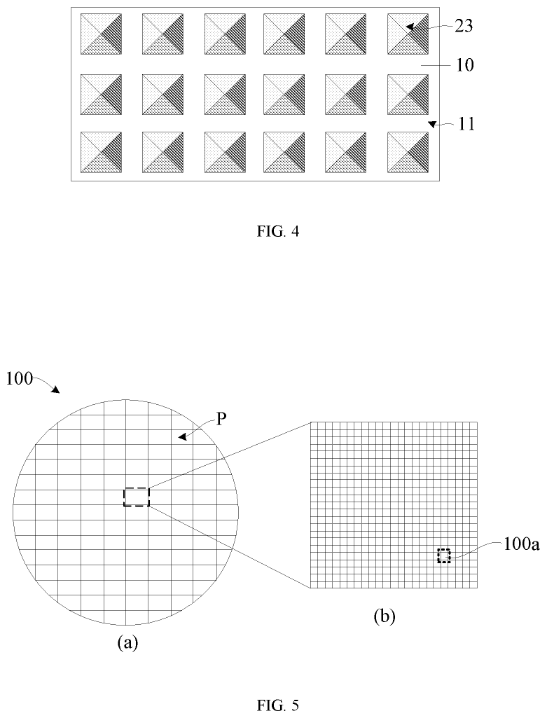

As shown in FIG. 3 and FIG. 4 which is a top view of FIG. 3, a wet etching process is used to etch the substrate exposed by the plurality of groove 21 to form light traps 23. One light trap 23 is an inverted pyramid structure.

The four side walls of the light trap 23 of the inverted pyramid structure serve as the photosensitive surfaces of the photoelectric sensor. For the increased performance requirements of the photoelectric sensor, the photosensitive area of the light trap 23 of the inverted pyramid structure is not large enough, and it is difficult to improve the light localization capability of the photoelectric sensor, making it difficult to meet the current performance requirements for the photoelectric sensor. Moreover, if the opening size of the light trap 23 is increased to increase the photosensitive area, the distance between adjacent light traps 23 will be reduced, since an etching mask is used to protect the areas that do not need to be etched during the process of forming the plurality of grooves 21 and the light traps 23, that is, an etching mask (not shown in the drawings) is also formed on the light-receiving surface 11 of the substrate. When the spacing between the adjacent light traps 23 is too small, the etching mask on the light-receiving surface may fall off easily during the wet etching process and fall into the pickling tank, thereby causing the pickling tank to be contaminated and affecting other subsequent processes using the pickling tank.

Therefore, it is currently difficult to obtain a larger photosensitive surface, thereby making it difficult to improve the photosensitive performance of the photoelectric sensor.

To at least partially alleviate the above technical problems, the present disclosure provides a fabrication method of a photoelectric sensor. A material of a substrate may belong to a cubic crystal system. In the material of the substrate, crystal planes and crystal directions of the same index are perpendicular to each other. In the present disclosure, the light-receiving surface may be a {100} crystal plane or a {110} crystal plane. Side walls of the first grooves may be perpendicular to the <100> crystal direction, and side walls of the corresponding second grooves may be also perpendicular to the <100> crystal direction. Among the etching rates of each crystal plane in the wet etching process, the etching rate for the {100} crystal plane may be the largest, and the etching rate for the {111} crystal plane may be the smallest. That is, the wet etching process may have the highest etching rate along the <100> crystal direction, and the smallest etching rate along the <111> crystal direction. Since a protective layer may be formed on the side walls of the first grooves, the side walls of the second groove may be etched before the side walls of the first grooves. In the process of etching the substrate exposed by the second grooves, the completed surface obtained by etching may gradually approach the {111} crystal plane, that is, the side walls of the second grooves may gradually become four {111} crystal planes. After the second grooves expose the {111} crystal planes, as the etching continues, the second grooves may expose the side walls of the first grooves. The sidewalls of the first grooves may be perpendicular to the <100> crystallographic direction. Therefore, the etching rate of the substrate at the exposed side walls of the first grooves may be accelerated, while the etching rate of the substrate of the {111} crystal plane exposed by the second grooves may be still slow. Because of the difference in etching rates between the two places, each {111} crystal plane may be etched to form two faces. Correspondingly, the aforementioned four {111} crystal planes may be etched to form totally eight faces. Therefore, after the initial light traps are connected in the row direction and the column direction to form the light traps, the shape of the protrusions surrounded by side walls of the light traps may be an eight-sided pyramid. In a pixel unit area, the eight sides and the top surface of each protrusion may be used as the photosensitive surface of the light sensor. Compared with the light trap with an inverted pyramid structure or a rectangle structure of the photoelectric sensor, the embodiments of the present disclosure may significantly increase the photosensitive area of the photoelectric sensor, and increase the number of reflections of incident light between the photosensitive surfaces. At the same time, the optical path difference of the incident light may be also increased, improving the light localization capability of the photoelectric sensor. The photosensitive performance of the photoelectric sensor may be improved.

The embodiments by the present disclosure will be described in following with reference to drawings, to illustrate the implementation and benefits of the present disclosure.

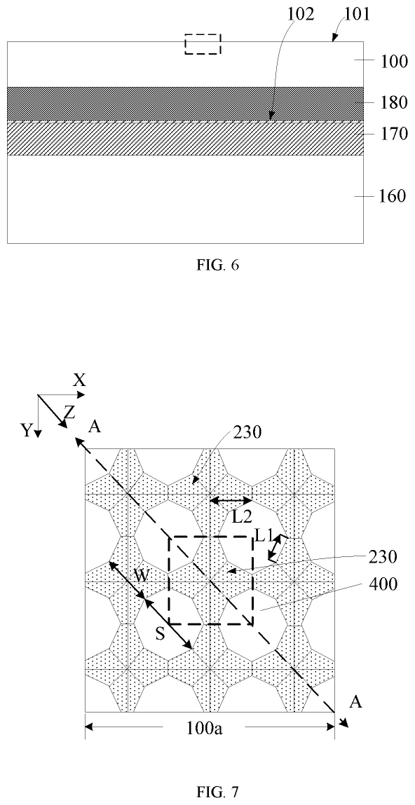

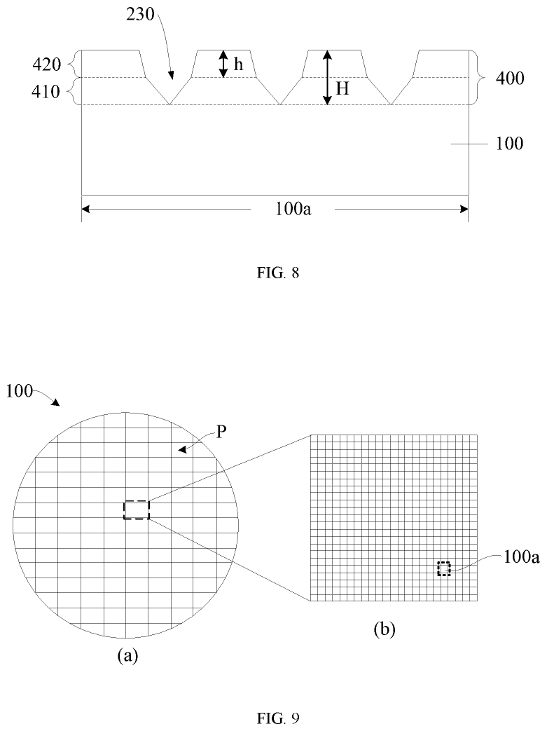

FIG. 5 to FIG. 8 illustrate a structure of a photoelectric sensor provided by one embodiment of the present disclosure. FIG. 5 is a top view, FIG. 5(b) is a locally enlarged view of any one photosensitive pixel area in FIG. 5(a), FIG. 6 is a cross-sectional view of FIG. 5(a), FIG. 7 is a partially enlarged top view of FIG. 6 at the position of the dotted line frame, and FIG. 8 is a cross-sectional view of FIG. 7 along the AA direction.

The photoelectric sensor may include: a substrate 100 including a light-receiving surface 101 and photosensitive pixel areas P each of which includes a plurality of pixel unit areas 100a distributed in a matrix; and a plurality of light traps 230 located in a partial thickness of the substrate 100 of the plurality of pixel unit areas 100a and located on the light-receiving surface 101 of the substrate 100. The plurality of light traps 230 may be arranged in a matrix along a row direction (the X direction in FIG. 7) and a column direction (the Y direction in FIG. 7). The row direction and the column direction may be perpendicular. Adjacent light traps 230 in the row direction may be connected, and adjacent light traps 230 in the column direction may be connected. Side walls of the plurality of light traps 230 may surround and form a plurality of adjacent protrusions 400, and the plurality of protrusions 400 may have a shape of an octagonal pyramid.

As an example, the embodiment where the photoelectric sensor is a time-of-flight sensor is used as an example to illustrate the present disclosure. More specifically, the photoelectric sensor may be a direct time-of-flight (DTOF) sensor.

In other embodiments, the photoelectric sensor may also be a charge coupled device (CCD) image sensor, a CMOS image sensor or an indirect time-of-flight (iTOF) sensor, etc.

In this embodiment, the substrate 100 may have a cubic crystal structure, and the material lattice of the substrate 100 may include a {100} crystal plane family, a {110} crystal plane family, and a {111} crystal plane family. The light-receiving surface 101 (that is, the top face of the substrate 100) may be the {100} crystal plane or the {110} crystal plane.

During the formation process of the photoelectric sensor, a partial thickness of the substrate 100 may be etched to form initial light traps. The initial light traps may be distributed in a matrix along the row and column directions, and side walls of the initial light traps may be perpendicular to the <100> crystal direction. Subsequently, a wet etching process may be used to etch the substrate exposed by the initial light traps, such that the initial light traps are connected in the row direction and the column direction, to form the plurality of light traps 230 and to utilize the side walls of the plurality of light traps 230 to form the plurality of protrusions 400. Among them, during the etching process using the wet etching, the etching solution may have the largest etching rate for the {100} crystal plane and the smallest etching rate for the {111} crystal plane. Since the {111} crystal plane and the {100} crystal plane has a certain angle, by using different etching rates for the {111} crystal plane and the {100} crystal plane, the plurality of light traps 230 each of which has eight inclined side walls may be formed, thereby obtaining the plurality of protrusions 400. The plurality of protrusions 400 may have a shape of an octagonal pyramid.

Specifically, the substrate 100 may be a silicon substrate, that is, the material of the substrate 100 may be silicon.

Silicon has a cubic crystal structure. Accordingly, TMAH solution may be used to wet-etch silicon. The TMAH solution may have the largest etching rate for the {100} crystal plane in the silicon lattice and the smallest etching rate for the {111} crystal plane. Then the difference in etching rates of the TMAH solution on different crystal planes of silicon may be used to form the plurality of protrusions 400 with a shape of an octagonal pyramid.

In other embodiments, the substrate may also be a silicon-on-insulator substrate.

The photosensitive pixel areas P may be used to receive optical signals to convert the optical signals into electrical signals.

In the substrate 100, there may be multiple photosensitive pixel areas P, and the multiple photosensitive pixel areas P may be distributed in a matrix. The plurality of pixel unit areas 100a may be used to form pixels.

In one embodiment, the substrate 100 may have a light-receiving surface 101. The light-receiving surface 101 may be the surface used to receive light illumination.

Optionally, the substrate 100 may be a pixel wafer, and the light-receiving surface 101 may be a first surface. The substrate 100 may also include a second surface 102 opposite to the first surface.

In one embodiment, the substrate 100 may be a backside illumination (BSI) pixel wafer. The light-receiving surface 101 may be the back side of the wafer, and the second surface 102 may be the front side of the wafer.

In the present embodiment, only a part of the photosensitive pixel areas P and the plurality of pixel unit areas 100a are shown in the figure. The plurality of pixel unit areas 100a may also include device structures such as optoelectronic elements (e.g., photodiodes). The photodiodes may be back-illuminated single photon avalanche diodes (SPADs). For the purpose of simplicity, the detailed structures of the above components are not shown in this embodiment.

In this embodiment, the substrate 100 may be used as the first substrate 100, and the photoelectric sensor may further include: a second substrate 160, used as a logic wafer and bonded to the first substrate 100.

The second substrate 160 may be used as a logic wafer for analyzing and processing electrical signals provided by the pixel wafer.

By arranging the photosensitive pixel areas P and the logic areas on two wafers respectively, and bonding the pixel wafer and the logic wafer together, a larger pixel area may be obtained, and it may be beneficial to shorten the path for light to reach the optoelectronic elements and to reduce the scattering of light, making the light more focused. Therefore, the photoelectric sensor's photosensitivity in low-light environments may be improved, reducing system noise and crosstalk.

In this embodiment, the second substrate 160 may be a silicon substrate. In other embodiments, the material of the second substrate may also be other materials such as germanium, silicon germanium, silicon carbide, gallium arsenide or indium gallium. The second substrate may also be a silicon-on-insulator substrate, a germanium-on-insulator substrate, or another type of substrates.

Correspondingly, in this embodiment, the second substrate 160 may also include logic transistors (not shown), which are used to logically process the electrical signals provided by the pixel wafer. Specifically, one logic transistor may include a logic gate structure located on the second substrate 160, and a logic drain region and a logic source region respectively located in the second substrate 160 on two sides of the logic gate structure.

In one embodiment, the second surface 102 of the first substrate 100 and the second substrate 160 may be bonded through hybrid bonding.

Specifically, in this embodiment, a first interconnection structure 180 may be formed on the second surface 102 of the first substrate 100, and a second interconnection structure 170 may be formed on the second substrate 160. The pixel wafer and the logic wafer may be bonded together by dielectric bonding, and then the first interconnection structure 180 and the second interconnection structure 170 may be electrically connected.

The first interconnection structure 180 may be first metal lines, or the first interconnection structure 180 may be first through silicon hole interconnection structures (TSV), or the first interconnection structure 180 may include first through silicon hole interconnection structures and first metal lines on the first through silicon hole interconnection structures. The second interconnection structure 180 may be second metal lines, or the second interconnection structure 180 may be second through silicon hole interconnection structures (TSV), or the second interconnection structure 180 may include second through silicon hole interconnection structures and second metal lines on the second through silicon hole interconnection structures.

It should be noted that the above bonding method between the first substrate 100 and the second substrate 160 is only an example, and the bonding method between the first substrate 100 and the second substrate 160 is not limited to this. For example: in other embodiments, the bonding method of the first substrate and the second substrate may also be direct bonding (such as fusion bonding or anodic bonding) or indirect bonding technology (such as metal eutectic thermocompression bonding or adhesive bonding), etc.

Correspondingly, in this embodiment, the light-receiving surface 101 of the first substrate 100 may be the light-receiving surface 101 that has been thinned

The plurality of light traps 230 may improve the optical transmittance of the photosensitive pixel areas P and increase the photoelectric conversion efficiency, thereby improving the optical sensitivity performance of the photoelectric sensor.

As shown in the dotted box in FIG. 7, one light trap 230 may include eight inclined side walls (i.e., inclined planes). The plurality of light traps 230 may be distributed in a matrix along the row direction and the column direction. Along the row direction, adjacent light traps 230 may be connected through the intersection of adjacent side walls, and along the column direction, adjacent light traps 230 may be connected. through the intersection of adjacent side walls. Therefore, adjacent light traps 230 in the row direction may be connected, and adjacent light traps 230 in the column direction may be connected.

The plurality of light traps 230 may be disposed above the photoelectric elements, which may slow down the change of the refractive index between the air and the first surface 101 to reduce the high reflectivity caused by the sudden change of the refractive index at the interface. Therefore, more light may be able to enter the photoelectric elements, and the transmittance of the incident light may be improved. Further, arranging the plurality of light traps 230 in the plurality of pixel unit areas 100a of the first surface 101, may be beneficial to disperse the incident light to multiple angles, increasing the effective optical path of light and playing a role in trapping light.

In the photoelectric sensor provided by the present disclosure, the plurality of light traps 230 may be distributed in a matrix along the row direction and the column direction. Adjacent light traps 230 in the row direction may be connected, and adjacent light traps 230 in the column direction may be connected. The side walls of the plurality of light traps 230 may surround and form the plurality of protrusions 400 adjacent of which are connected. The plurality of protrusions 400 may have a shape of an octagonal pyramid. In the plurality of pixel unit areas 100a, the eight side surfaces and the top surface of each protrusion 400 may be used as the photosensitive surfaces of one corresponding light sensor. Compared with photoelectric sensors with light traps which have an inverted pyramid structure or a rectangular structure, the photosensitive area of the photoelectric sensor in the present disclosure may be increased significantly. Further, the number of reflections of the incident optical fiber between the photosensitive surfaces may be increased, and, at the same time, the optical path difference of the incident optical fiber may be also increased, which is beneficial to improving the optical localization of the photoelectric sensor and improving the photosensitive performance of the photoelectric sensor.

The number of the plurality of light traps 230 may be multiple, thereby increasing the density of the light traps 230 in each pixel unit area 100a. Also, the plurality of light traps 230 may be distributed in a matrix along the row direction and the column direction. Adjacent light traps 230 in the row direction may be connected, and adjacent light traps 230 in the column direction may be connected. The optical transmittance may be increased further.

The density of the light traps 230 may be the ratio of the sum of the opening areas of all the light traps 230 in the photosensitive pixel area P to the sum of the areas of the top surfaces of the protrusions 400 in the photosensitive pixel area P.

In the present disclosure, when forming the photoelectric sensor, the plurality of discrete initial light traps may be first formed, and then an etching process may be used to connect the plurality of discrete initial light traps, thereby obtaining the plurality of the light traps 230. And, the plurality of the initial light traps may be arranged in an array in each pixel unit area 100a, such that adjacent light traps 230 in the row direction may be connected and adjacent light traps 230 in the column direction may be connected, which not only facilitates layout design and layout, but also helps maximize the number of the plurality of initial light traps in one single pixel unit area 100a, thereby further increasing the density of the plurality of light traps 230.

In one embodiment, the side walls of the plurality of light traps 230 may surround and form the plurality of protrusions 400 adjacent protrusions of which are connected.

Each light trap 230 may have eight inclined side walls. Also, the plurality of light traps 230 may be distributed in a matrix along the row direction and the column direction. Along the row direction, adjacent light traps 230 may be connected through the intersection of adjacent side walls. Along the column direction, adjacent light traps 230 may be connected through the intersection of adjacent side walls. Therefore, side walls of four connected light traps 230 may surround and from one protrusion 400 in the shape of an octagonal pyramid.

In the present embodiment, the plurality of light traps 230 may be connected in the row direction and in the column direction. Therefore, the number of the protrusions 400 in each pixel unit area 100a may be multiple. The plurality of protrusions 400 in each pixel unit area 110a may be arranged in a matrix in the row direction and in the column direction.

In one embodiment, a shape of a top surface of one protrusion 400 may be an octagon. Along an extending direction of a longest diagonal line in the octagon (as shown in the Z direction in FIG. 7), a length of the diagonal line of the top surface of the octagon may be a first length S. The extending direction of the longest diagonal line may have an included angle with both the row direction and the column direction.

It should be noted that the first length S should not be too large or too small. When the first length S is too large, the distance between adjacent light trap grooves 230 along the extending direction of the longest diagonal line may be too large, and the area percentage occupied by the top surface area of the protrusion 400 in the corresponding pixel unit area 100a may be too large. Correspondingly, the density of the plurality of light traps 230 may be too small, and it may be difficult to obtain a larger photosensitive area, thereby making it difficult to improve the performance of the photoelectric sensor. When the first length S is too small, the top surface area of the protrusion 400 may be too small. An etching mask may be used to protect the area that does not need to be etched during the etching process for forming the plurality of light traps 230, that is, an etching mask (not shown) may be also formed on the plurality of protrusions 400. When the top surface area of the protrusion 400 is too small, the etching mask on the plurality of protrusions 400 may fall off and fall into the pickling tank easily during the etching process for forming the plurality of light traps 230, thereby causing the contamination of the pickling tank and affecting other subsequent processes using the pickling tank. Therefore, in this embodiment, the first length S may be set to 250 nm to 350 nm.

In one embodiment, in adjacent protrusions 400 along the extending direction of the longest diagonal line, an extending direction of a line connecting the opposite vertices of adjacent protrusions 400 may coincide with the extending direction of the longest diagonal line, and a distance between the opposite vertices of adjacent protrusions 400 may be the second length W.

It should be noted that the second length W should not be too large or too small. When the second length W is too large, the first length S may be too small correspondingly. Therefore, the top surface area of the protrusion 400 may be too small, and the etching mask on the plurality of protrusions 400 may fall off and fall into the pickling tank easily during the etching process for forming the plurality of light traps 230, thereby causing the contamination of the pickling tank and affecting other subsequent processes using the pickling tank. When the second length W is too small, the first length S may be too large correspondingly. Therefore, the density of the plurality of light traps 230 may be too small, and it may be difficult to obtain a larger photosensitive area, thereby making it difficult to improve the performance of the photoelectric sensor. Therefore, in this embodiment, the second length W may be set to 250 nm to 350 nm.

In one embodiment, the first length S and the second length W may be equal. Therefore, along the extending direction of the longest diagonal line, the dimensions of the plurality of light traps 230 and the plurality of protrusions 400 may be in the form of 1:1, which is beneficial to maximization of the number of the plurality of light traps 230. Therefore, the density of the plurality of light traps 230 may be increased further, obtaining a larger photosensitive area. At the same time, sufficient top surface area of the plurality of protrusions 400 may be ensured to provide sufficient support for the etching mask as much as possible. This may avoid increasing process difficulty due to excessive density of the plurality of light traps 230 and improve process compatibility for forming the plurality of light traps 230.

The height H of the plurality of protrusions 400 should not be too large or too small. Since the plurality of light traps 230 and the plurality of protrusions 400 are formed by etching part of the thickness of the substrate 100, when the height H of the plurality of protrusions 400 is too large, the remaining thickness of the substrate 100 may be too small, that is, the thickness of the base 100 at the bottom of the plurality of protrusions 400 may be too small and the photon absorption capacity of the light incident on the bottom of the plurality of protrusions 400 may be poor. Especially for incident light with longer wavelengths such as near infrared rays, the light absorption efficiency of the substrate 100 at the bottom of the plurality of protrusions 400 may be lower, thereby affecting the light absorption of the photoelectric sensor. When the height H of the plurality of protrusions 400 is too small, the height of the plurality of light traps 230 may be too small, and the height of the plurality of initial light traps may be too small. Therefore, the amount of substrate 100 to be etched on the side of the plurality of initial light traps may be too small, resulting in etching the side walls of the initial light trap too quickly, that is, etching the {100} crystal plane to transform into the {111} crystal plane too quickly. After transforming into the {111} crystal plane, the etching rate may decrease. The process time for forming the plurality of light traps 230 may be increased and the process efficiency may be reduced, making it difficult to form the octagonal pyramid profile. Also, when the height H of the plurality of protrusions 400 is too small, the slope of the side walls of the plurality of protrusions 400 may be too small, that is, the slope of the side walls of the plurality of light traps 230 may be too small. Correspondingly, the number of reflections of the incident light may be too small, making it difficult to increase the optical path difference and difficult to improve the photosensitive performance of the photoelectric sensor. Therefore, in this embodiment, the height H of the plurality of protrusions 400 may be set to 300 nm to 400 nm.

In this embodiment, the shape of the top surfaces of the plurality of protrusions 400 may be octagonal. It should be noted that the side length L1 of the octagon corresponding to the top surfaces of the plurality of protrusions 400 should not be too large or too small. When the side length L1 of the octagon is too large, the area of the octagon may be too large, that is to say, the area of the top surfaces of the plurality of protrusions 400 may be too large, Therefore, the density of the plurality of light traps 230 may be too small and it may be difficult to obtain a larger photosensitive area and improve the performance of the photoelectric sensor. When the side length L1 of the octagon is too small, the area of the octagon may be too small, that is, the area of the top surfaces of the plurality of protrusions 400 may be too small. When the top surface area of the protrusion 400 is too small, the etching mask on the plurality of protrusions 400 may fall off and fall into the pickling tank easily during the etching process for forming the plurality of light traps 230, thereby causing the contamination of the pickling tank and affecting other subsequent processes using the pickling tank. Therefore, in this embodiment, the side length L of the octagons corresponding to the plurality of protrusions 400 may be set to 100 nm to 150 nm.

In this embodiment, the shape of the bottom surfaces of the plurality of protrusions 400 may be octagonal. It should be noted that the side length L2 of the octagon corresponding to the bottom surfaces of the plurality of protrusions 400 should not be too large or too small. The plurality of light traps 230 are obtained by etching the substrate 100 exposed by the plurality of initial light traps such that the plurality of discrete initial light traps us connected. The bottom surface of the plurality of protrusions 400 may be obtained by etching bottoms of the plurality of initial light traps, and the plurality of initial light traps may have square openings. When the side length L2 of the octagon is too large, the bottom size of the plurality of initial light traps may be too large and the opening size of the plurality of initial light traps may be correspondingly too large. Therefore, the top surface area of the substrate 100 outside the plurality of initial light traps may be too small. The substrate 100 outside the plurality of initial light traps may be used to form the plurality of protrusions 400, and the area of the top surfaces of the plurality of protrusions 400 may be too small. When the top surface area of the protrusion 400 is too small, the etching mask on the plurality of protrusions 400 may fall off and fall into the pickling tank easily during the etching process for forming the plurality of light traps 230, thereby causing the contamination of the pickling tank and affecting other subsequent processes using the pickling tank. When the side length L2 of the octagon is too small, the opening size of the plurality of initial light traps may be correspondingly too large and the opening size of the plurality of light traps 230 may be too small. Therefore, it may be difficult to obtain a large photosensitive area and improve the performance of the photoelectric sensor. Therefore, in this embodiment, the side length L2 of the octagons corresponding to the bottom surfaces of the plurality of protrusions 400 may be set to 200 nm to 300 nm.

The plurality light traps 230 may include: in the plurality of pixel unit areas 100a, forming a plurality of discrete initial light traps on the light-receiving surface 101 of the substrate 100; and using a wet etching process to etch the substrate 100 exposed by the plurality of initial light traps, such that the plurality of initial light traps connects in the row direction and in the column direction respectively to form the plurality of light traps 230 and the plurality of protrusions 400 formed by the side walls of the plurality of light traps 230.

When using a wet etching process to etch the substrate 100 exposed by the plurality of initial light traps, a portion of the substrate 100 above the bottom surfaces of the plurality of initial light traps may be etched to form a portion of the plurality of protrusions 400, and another portion of the substrate 100 below the bottom surfaces of the plurality of initial light traps may be etched to form a remaining portion of the plurality of protrusions 400. Therefore, in this embodiment, one protrusion 400 may include a bottom protrusion 410 and a top protrusion 420 located on the bottom protrusion 410. Both the bottom protrusion 410 and the top protrusion 420 may be octagonal pyramids. The bottom surface of the top protrusion 420 and the top surface of the bottom protrusion 410 may coincide.

Further, when forming the plurality of initial light traps, an etching mask may be used to protect the areas that do not need to be etched. That is, the etching mask may be formed on the substrate 100 outside the plurality of initial light traps. During the wet etching process, the top of the portion of the substrate 100 above the bottom surfaces of the plurality of initial light traps may be etched more slowly, and the amount of etching solution in contact with the top may be small. Therefore, the etched amount of the portion of the substrate 100 above the bottom surfaces of the plurality of initial light traps may be smaller. The portion of the substrate 100 below the bottom surfaces of the plurality of initial light traps may be etched more quickly, and the amount of etching solution in contact with the portion of the substrate 100 below the bottom surfaces of the plurality of initial light traps may be larger. Therefore, the etched amount of the portion of the substrate 100 below the bottom surfaces of the plurality of initial light traps may be larger. Correspondingly, in this embodiment, the slope of the side wall of the bottom protrusion 410 may be larger than the slope of the side wall of the top protrusion 420.

When using a wet etching process to etch the substrate 100 exposed by the plurality of initial light traps, the etching solution may have the largest etching rate for the {100} crystal plane and the smallest etching rate for the {111} crystal plane. Since the {111} crystal plane and the {100} crystal plane has a certain angle, by using different etching rates for the {111} crystal plane and the {100} crystal plane, the plurality of light traps 230 each of which has eight inclined side walls may be formed, thereby obtaining the plurality of protrusions 400. The plurality of protrusions 400 may have a shape of an octagonal pyramid.

The height h of the top protrusion 420 should not be too large, nor should it be too small. When the height h of the top protrusion 420 is too large, that is, the depth of one corresponding initial light trap is too large, it may easily lead to the slope of the side wall of the upper half of one corresponding light trap 230 being too small. Therefore, it may be difficult for the light trap 230 to disperse the incident light to multiple angles and to increase the effective optical path of the light, making the light trapping function difficult to realize. When the height h of the top protrusion 420 is too small, that is, when the depth of the initial trap is too small, it may be difficult for the initial trap to expose a sufficient area of the sidewall. During the wet etching process, it may be difficult to achieve etching of the sidewall at a relatively high rate. Therefore, it may be difficult to use the difference in etching rates on different surfaces to form the protrusion 400 in the shape of an octagonal pyramid, and also it may be easy to eventually form a light trap with only four surfaces and difficult to obtain a larger photosensitive area, making it difficult to improve the performance of the photoelectric sensor. Therefore, in this embodiment, the height h of the top protrusion 420 may be set to 100 nm to 150 nm.

In this embodiment, a portion of the thickness of the substrate 100 may be etched to form the plurality of light traps 230, and the side walls of the plurality of light traps 230 may be used to surround and form the plurality of protrusions 400. Therefore, the plurality of protrusions 400 and the substrate 100 may be an integral structure, and the plurality of protrusions 400 may be made of a material including silicon.

In this embodiment, the photoelectric sensor may further include a dielectric structure layer (not shown). The dielectric structure layer may include: a conformal dielectric layer (not shown) located on the surface of the plurality of light traps 230 and the top surface of the plurality of protrusions 400; and a light-transmitting layer (not shown), located on the conformal dielectric layer in the plurality of light traps 230 and filled in the plurality of light traps 230.

The conformal dielectric layer may electrically isolate adjacent pixel unit areas 100a, which helps prevent electrical crosstalk between adjacent pixel unit areas 100a.

The light-transmissive layer may fill the plurality of light traps 230, and may be beneficial to ensure the effect of the plurality of light traps 230 in improving the optical transmittance of the photosensitive pixel areas P and improving process integration and process compatibility. Further, the light-transmitting layer may be also used to make each film layer on the light-receiving surface 101 a flat surface.

The specific description of the dielectric structure layer will not be described again here.

The present disclosure also provides a fabrication method of a photoelectric sensor. FIG. 9 to FIG. 26 illustrate structures corresponding to certain stages of a fabrication method of a photoelectric sensor.

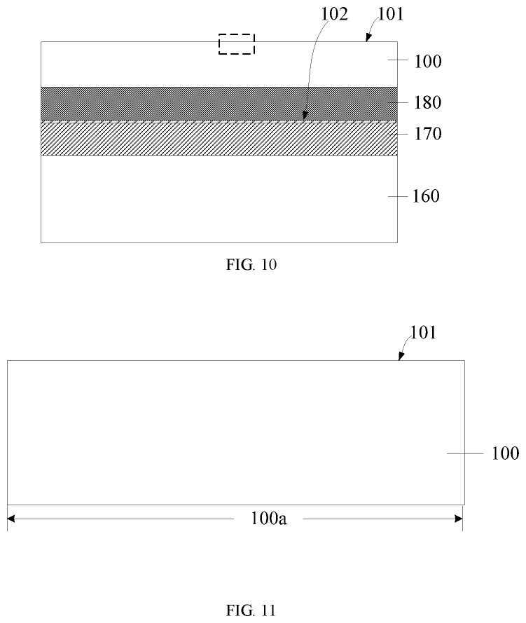

FIG. 9(a) is a top view of the substrate, FIG. 9(b) is a partially enlarged view of one photosensitive pixel area in FIG. 9(a), FIG. 10 is a cross-sectional view corresponding to FIG. 9(a), and FIG. 11 is a partially enlarged view at the position of the dotted line frame of FIG. 10. As shown in FIG. 9 to FIG. 11, a substrate 100 may be provided. The substrate 100 may include a light-receiving surface 101 and photosensitive pixel areas P. Each of the photosensitive pixel areas P may include a plurality of pixel unit areas 100a distributed in a matrix. The substrate 100 may have a cubic crystal structure, and the material lattice of the substrate 100 may include a {100} crystal plane family, a {110} crystal plane family, and a {111} crystal plane family. The light-receiving surface 101 (that is, the top face of the substrate 100) may be the {100} crystal plane or the {110} crystal plane.

As an example, the embodiment where the photoelectric sensor is a time-of-flight sensor is used as an example to illustrate the present disclosure. More specifically, the photoelectric sensor may be a direct time-of-flight (DTOF) sensor.

In other embodiments, the photoelectric sensor may also be a charge coupled device (CCD) image sensor, a CMOS image sensor or an indirect time-of-flight (iTOF) sensor, etc.

The substrate 100 may be used to provide a process platform for subsequent processes.

The substrate 100 may have a cubic crystal structure. Then the crystal planes and crystal directions of the same index are perpendicular to each other. Therefore, in the subsequent etching process of the substrate 100, the crystal planes may be etched along the corresponding crystal directions. The material lattice of the substrate 100 may include a {100} crystal plane family, a {110} crystal plane family, and a {111} crystal plane family. There may be crystal faces perpendicular to each other in the {100} crystal face family, and there may be also crystal faces perpendicular to the {100} crystal face in the {110} crystal face family. Therefore, regardless of whether the light-receiving surface 101 is a {100} crystal plane or a {110} crystal plane, first grooves with side walls of the {100} crystal plane may be formed subsequently. Since the {111} crystal plane and the {100} crystal plane has a certain angle, by using different etching rates for the {111} crystal plane and the {100} crystal plane, the plurality of light traps with inclined side walls may be formed, thereby obtaining the plurality of protrusions with a shape of an octagonal pyramid through the sidewalls of the plurality of light traps.

In one embodiment, the substrate 100 may be a material including silicon. Silicon has a cubic crystal structure. The crystal lattice of silicon may include a {100} crystal plane family, a {110} crystal plane family, and a {111} crystal plane family.

In one embodiment, the light-receiving surface 101 (that is, the top face of the substrate 100) may be the {100} crystal plane or the {110} crystal plane. Therefore, side walls of first grooves subsequently formed in the light-receiving surface 101 may be perpendicular to the <100> crystal direction. As an example, the light-receiving surface 101 may be the {100} crystal plane.

The photosensitive pixel areas P may be used to receive optical signals to convert the optical signals into electrical signals.

In the substrate 100, there may be multiple photosensitive pixel areas P, and the multiple photosensitive pixel areas P may be distributed in a matrix. The plurality of pixel unit areas 100a may be used to form pixels.

In one embodiment, the substrate 100 may have a light-receiving surface 101. The light-receiving surface 101 may be the surface used to receive light illumination.

Optionally, the substrate 100 may be a pixel wafer, and the light-receiving surface 101 may be a first surface. The substrate 100 may also include a second surface 102 opposite to the first surface.

In one embodiment, the substrate 100 may be a backside illumination (BSI) pixel wafer. The light-receiving surface 101 may be the back side of the wafer, and the second surface 102 may be the front side of the wafer.

In the present embodiment, only a part of the photosensitive pixel areas P and the plurality of pixel unit areas 100a are shown in the figure. The plurality of pixel unit areas 100a may also include device structures such as optoelectronic elements (e.g., photodiodes). The photodiodes may be back-illuminated single photon avalanche diodes (SPADs). For the purpose of simplicity, the detailed structures of the above components are not shown in this embodiment.

In this embodiment, the substrate 100 may be used as the first substrate 100, and the photoelectric sensor may further include: a second substrate 160, used as a logic wafer and bonded to the first substrate 100.

The second substrate 160 may be used as a logic wafer for analyzing and processing electrical signals provided by the pixel wafer.

By arranging the photosensitive pixel areas P and the logic areas on two wafers respectively, and bonding the pixel wafer and the logic wafer together, a larger pixel area may be obtained, and it may be beneficial to shorten the path for light to reach the optoelectronic elements and to reduce the scattering of light, making the light more focused. Therefore, the photoelectric sensor's photosensitivity in low-light environments may be improved, reducing system noise and crosstalk.

In this embodiment, the second substrate 160 may be a silicon substrate. In other embodiments, the material of the second substrate may also be other materials such as germanium, silicon germanium, silicon carbide, gallium arsenide or indium gallium. The second substrate may also be a silicon-on-insulator substrate, a germanium-on-insulator substrate, or another type of substrates.

Correspondingly, in this embodiment, the second substrate 160 may also include logic transistors (not shown), which are used to logically process the electrical signals provided by the pixel wafer. Specifically, one logic transistor may include a logic gate structure located on the second substrate 160, and a logic drain region and a logic source region respectively located in the second substrate 160 on two sides of the logic gate structure.

In one embodiment, the second surface 102 of the first substrate 100 and the second substrate 160 may be bonded through hybrid bonding.

Specifically, in this embodiment, a first interconnection structure 180 may be formed on the second surface 102 of the first substrate 100, and a second interconnection structure 170 may be formed on the second substrate 160. The pixel wafer and the logic wafer may be bonded together by dielectric bonding, and then the first interconnection structure 180 and the second interconnection structure 170 may be electrically connected.

The first interconnection structure 180 may be first metal lines, or the first interconnection structure 180 may be first through silicon hole interconnection structures (TSV), or the first interconnection structure 180 may include first through silicon hole interconnection structures and first metal lines on the first through silicon hole interconnection structures. The second interconnection structure 180 may be second metal lines, or the second interconnection structure 180 may be second through silicon hole interconnection structures (TSV), or the second interconnection structure 180 may include second through silicon hole interconnection structures and second metal lines on the second through silicon hole interconnection structures.

It should be noted that the above bonding method between the first substrate 100 and the second substrate 160 is only an example, and the bonding method between the first substrate 100 and the second substrate 160 is not limited to this. For example: in other embodiments, the bonding method of the first substrate and the second substrate may also be direct bonding (such as fusion bonding or anodic bonding) or indirect bonding technology (such as metal eutectic thermocompression bonding or adhesive bonding), etc.

In one embodiment, the fabrication method of the photoelectric sensor may further include: after bonding the second surface 102 of the first substrate 100 and the second substrate 160, thinning the light-receiving surface 101 of the first substrate 100.

Thinning the light-receiving surface 101 of the first substrate 100 may reduce the thickness of the first substrate 100, and corresponding reduce the overall thickness of the photoelectric sensor.

In one embodiment, the light-receiving surface 101 of the first substrate 100 may be thinned by a chemical mechanical polishing process. The chemical mechanical polishing process is a global planarizing process, and may be beneficial to improve the overall flatness of the surface of the device to provide a flat and smooth surface for subsequent processes.

The process for thinning the light-receiving surface 101 of the first substrate 100 is not limited to this. For example, in some other embodiments, the thinning process may include an etching process, or a combination of the etching process and the chemical mechanical polishing process.

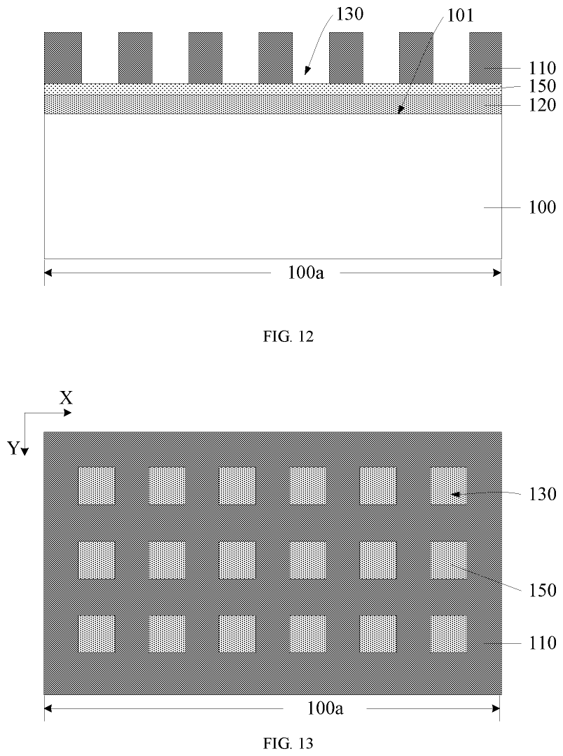

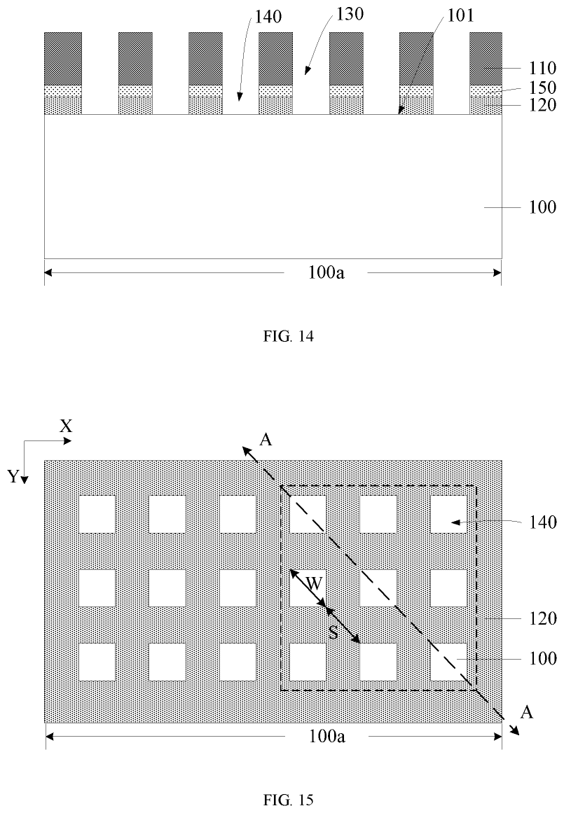

As shown in FIG. 12 which is a cross-sectional view after forming photoresist based on FIG. 11, FIG. 13 which is a top view of FIG. 12, and FIG. 14 which is a cross-sectional view after forming a mask layer based on FIG. 12, the method may further include: forming a mask layer 120 on the substrate 100.

The mask layer 120 may be used as an etching mask for subsequently patterning the substrate 100.

In this embodiment, the mask layer 120 may be made of a material including plasma enhanced tetraethyl orthosilicate (PETEOS). Plasma enhanced tetraethyl orthosilicate has a faster deposition rate and a shorter time to form the mask layer 120, which is beneficial to improving process efficiency. In other embodiments, the mask layer 120 may be made of a material including SiO2 or SiN, or the mask layer may be formed through an in-situ stream generation (ISSG) process.

In this embodiment, before forming a plurality of discrete first grooves in the light-receiving surface 101 of the substrate 100, the method may further include: patterning the mask layer 120 to form first openings 140 in the mask layer 120. The first opening 140 may be square openings or circular openings.

According to process requirements, the first grooves formed subsequently may be square openings or circular openings. Therefore, the first opening 140 may be square openings or circular openings.

The first openings 130 may be used as a mask opening for patterning the substrate 100, and the substrate 100 may be etched along the mask opening, which is beneficial to improving the stability of the patterning process and the accuracy of pattern transfer.

As shown in FIG. 12 and FIG. 13, patterning the mask layer 120 may include: forming photoresist 110 including second openings 130 on the mask layer 120. The second opening 130 may be square openings or circular openings.

According to process requirements, the first openings 140 may be square openings or circular openings. Therefore, the second openings 130 may be square openings or circular openings.

In this embodiment, the second openings 130 may be distributed in a matrix along the row direction (the X direction in FIG. 13) and column direction (the Y direction in FIG. 13), preparing for the subsequent formation of the first grooves distributed in a matrix.

In this embodiment, an anti-reflective coating 150 may be also formed between the photoresist 110 and the mask layer 120. In this embodiment, the anti-reflective layer 150 may be made a material including a Si-ARC (silicon-containing anti-reflective coating) material.

As shown in FIG. 14, the mask layer 120 exposed by the second openings 130 may be removed, to form the first openings 140 in the mask layer 120.

In one embodiment, along the second openings 130, the anti-reflective coating 150 and the mask layer 120 may be sequentially etched to form the first openings 140.

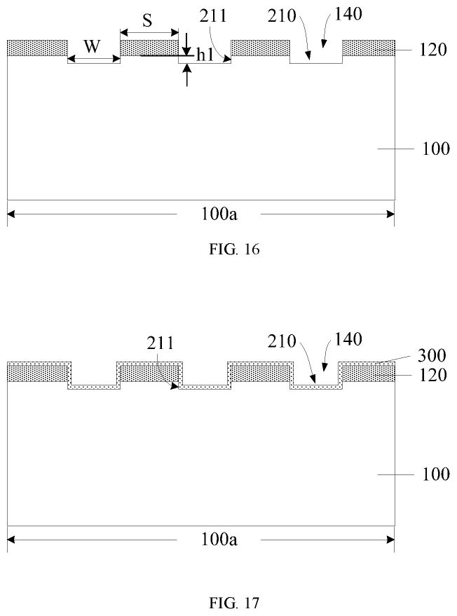

As shown in FIG. 15 which is a top view based on FIG. 13 and FIG. 16 which is a cross-sectional view along the AA direction in FIG. 15, in the plurality of pixel unit areas 100a, a plurality of discrete first grooves 210 may be formed on the light-receiving surface 101 of the substrate 100. The plurality of first grooves 210 may be square grooves or circular grooves. The side walls 211 of the plurality of grooves 210 may be perpendicular to the <100> crystallographic direction, and the plurality of first grooves 210 may be distributed in a matrix along the row direction (the X direction in FIG. 15) and the column direction (the Y direction in FIG. 15). The row direction and the column direction may be perpendicular.

The plurality of first grooves 210 may expose surfaces perpendicular to the <100> crystal direction, which is used to provide a surface perpendicular to the <100> crystal direction for subsequent formation of light traps.

In one embodiment, the plurality of first grooves may be square grooves, and the side walls of the plurality of first grooves 210 may be {100} crystal planes perpendicular to the <100> crystal direction. In other embodiments, the plurality of first grooves may also be circular grooves, and the side walls of the plurality of circular grooves may still be perpendicular to the <100> crystallographic direction.

It should be noted that in other embodiments, the top surface of the substrate may also be a {110} crystal plane. To form the plurality of first grooves with side walls perpendicular to the <100> crystal direction, the row and column directions in previous embodiments, may be rotated clockwise as a whole by 45°.

In one embodiment, the number of first grooves 210 located in each of the pixel unit areas 100a may be multiple, and the plurality of first grooves 210 may be distributed in a matrix in the pixel unit area 100a.

The number of first grooves 210 located in each of the pixel unit areas 100a may be multiple, to increase the density of light traps subsequently formed in each pixel unit area 100a and further increase the light transmittance. The plurality of first grooves 210 may be distributed in a matrix in the pixel unit area 100a, which not only facilitates layout design and layout, but also helps maximize the number of light traps in one single pixel unit area 100a, thereby further increasing the density of the plurality of light traps. The plurality of first grooves 210 arranged in a matrix may prepare for forming light traps arranged in a matrix and forming protrusions arranged in a matrix from sidewalls of light traps.

In one embodiment, the plurality of first grooves 210 may be square grooves, and the shapes of the plurality of first grooves 210 may be square, which may be beneficial to interconnection of adjacent light traps formed subsequently in the row direction and the column direction respectively. Also, light traps with a relatively regular profile may be formed and accordingly protrusion with a relatively regular profile may be surrounded and formed by the side walls of light traps. For example, the shape of the top surface of the protrusions may be closer to a regular octagon.

In one embodiment, forming the plurality of discrete first grooves 210 in the light-receiving surface 101 of the substrate 100 may include: using the mask layer 120 as a mask, removing a portion of the thickness of the substrate 100 exposed by the first openings 140.

In one embodiment, a dry etching process is used to form the plurality of first grooves 210.

The dry etching process is an anisotropic etching dry etching process. Its longitudinal etching rate is much larger than the lateral etching rate, and the accurate pattern conversion along the first openings 140 may be obtained to form the plurality of first grooves 210 whose side walls are perpendicular to the <100> crystallographic direction. It may be also beneficial to improving the sidewall topography quality and dimensional accuracy of the plurality of first grooves 210. Also, the process parameters of the dry etching process may be easy to control, which is beneficial to controlling the thickness of the removed substrate 100 and forming the plurality of first grooves 210 with a target depth.

In this embodiment, the matrix distribution may also include a diagonal direction, and the diagonal direction may have an angle with both the row direction and the column direction. The plurality of first grooves 210 may be square grooves. The diagonal extending direction of the top of the plurality of first grooves 210 may coincide with the diagonal direction. Along the diagonal direction, the distance between the vertices of adjacent first grooves 210 may be the first length S, and the diagonal length of the top of the plurality of first grooves 210 may be the second length W.

It should be noted that the first length S should not be too large or too small. When the first length S is too large, the distance between adjacent first grooves 210 along the diagonal direction may be too large and the opening size of the plurality of first grooves 210 may be too small. Therefore, the opening size of light traps formed subsequently may be too small, and it may be difficult to obtain a larger photosensitive area, thereby making it difficult to improve the performance of the photoelectric sensor. When the first length S is too small, the distance between the adjacent first grooves 210 along the diagonal direction may be too small. When forming light traps subsequently, the area of the light-receiving surface exposed by light traps may be too small. Since the mask layer 120 may be also formed on the light-receiving surface 101, when the area of the light-receiving surface exposed by light traps is too small, the mask layer on the p the light-receiving surface 101 may fall off and fall into the pickling tank easily during the etching process for forming light traps, thereby causing the contamination of the pickling tank and affecting other subsequent processes using the pickling tank. Therefore, in this embodiment, the first length S may be set to 250 nm to 350 nm.

It should be noted that the second length W should not be too large or too small. When the second length W is too large, the first length S may be too small correspondingly. When forming light traps subsequently, the area of the light-receiving surface exposed by light traps may be too small, and the mask layer on the light-receiving surface 101 may fall off and fall into the pickling tank easily during the etching process for forming light traps, thereby causing the contamination of the pickling tank and affecting other subsequent processes using the pickling tank. When the second length W is too small, the opening size of the plurality of first grooves 210 may be too small. Therefore, the opening size of light traps formed subsequently may be too small, and it may be difficult to obtain a larger photosensitive area, thereby making it difficult to improve the performance of the photoelectric sensor. Therefore, in this embodiment, the second length W may be set to 250 nm to 350 nm.

In one embodiment, the first length S and the second length W may be equal. Therefore, along the extending direction of the longest diagonal line, the dimensions of the plurality of light traps and the plurality of protrusions may be in the form of 1:1, which is beneficial to maximization of the number of the plurality of first grooves 210. Therefore, the density of the plurality of light traps formed subsequently may be increased further, obtaining a larger photosensitive area. At the same time, sufficient area of the light-receiving surface 101 exposed by the plurality of first grooves may be ensured to provide sufficient support for the mask layer 120 as much as possible. This may avoid increasing process difficulty due to excessive density of the plurality of first grooves 210 and improve process compatibility for forming the plurality of first grooves 210.

In other embodiments, the plurality of first grooves 210 may be circular grooves. Therefore, a line connecting the circular centers of adjacent first grooves in the diagonal direction may coincide with the diagonal direction. Along the diagonal direction, the distance between the boundaries of adjacent first grooves may be the first length, and the diameter of the plurality of first grooves 210 may be the second length.

The depth h1 of the plurality of first grooves 210 should not be too large or too small. When the depth h1 of the f plurality of first grooves 210 is too large, unnecessary waste may be caused on the basis that the plurality of first grooves 210 exposes a sufficient area of the side walls 211. Further, it may be necessary to form the protective layer on the side walls 211. After the protective layer is formed, during the etching process of the substrate 100, the etching solution may also need to contact the side walls 211 covered by the protective layer. Therefore, when the depth h1 of the plurality of first grooves 210 is too large, it may be difficult to etch the side walls 211 of the plurality of first grooves 210. When the depth h1 of the plurality of first grooves 210 is too small, it may be difficult for the plurality of first grooves 210 to expose a sufficient area of the side walls 211. Therefore, in the subsequent step of etching the substrate 100 to form light traps, it may be difficult for the plurality of first grooves 210 to provide the {100} crystal plane. Correspondingly, it may be difficult to form light traps with eight side walls, and a larger photosensitive area may be difficult to obtain. The performance of the photoelectric sensor may not be improved. Therefore, in this embodiment, the depth h1 of the plurality of first grooves 210 may be set to 100 Å to 300 Å.

In one embodiment, after forming the plurality of first grooves 210, the method may further include removing the photoresist 110.

In one embodiment, a wet etching process may be used to remove the photoresist 110 and the anti-reflective layer 150 together. The wet etching process has the characteristics of isotropic etching, which is beneficial to completely removing the photoresist 110 and the anti-reflective layer 150.

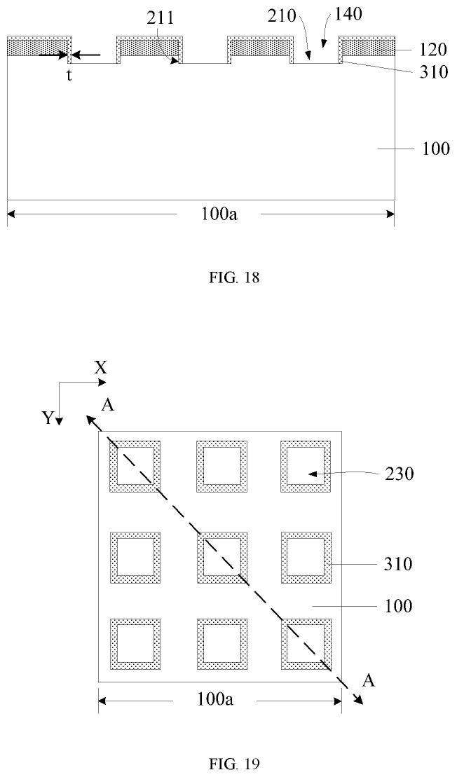

As shown in FIG. 17 and FIG. 18 which are cross-sectional view based on FIG. 16, a protective layer 310 may be formed on the side walls of the plurality of first grooves 210.

The protective layer 310 may be used to cover the side walls of the plurality of first grooves 210. Therefore, in the step of etching the substrate 100 exposed by the second grooves after the second grooves are subsequently formed, the side walls 211 of the plurality of first grooves 210 may not be etched in the beginning. After the etching is performed for some time, the etching solution may contact the side walls 211 of the plurality of first grooves 210 to perform etching.

In this embodiment, the protective layer 310 may be made of a material including silicon oxide.

Silicon oxide and silicon may have a large etching selectivity ratio, such that the protective layer 310 may better protect the side walls of the plurality of first grooves 210 when subsequently etching the substrate 1000 exposed by the second grooves.

In this embodiment, after forming the protective layer 310, a portion of the thickness of the substrate 100 exposed by the plurality of first grooves 210 may be removed, to form second grooves connected to the f plurality of first grooves 210. After forming the second grooves, a wet etching process may be used to etch the substrate 100 exposed by the second grooves. During the etching process, the side walls of the second grooves may be etched first until the side walls 211 of the plurality of first grooves 210 covered by the protective layer 310 are exposed, and the side walls 211 of the plurality of first grooves 210 may be etched.

Along the direction perpendicular to the side walls 211 of the plurality of first grooves 210, the thickness t of the protective layer 310 should not be too large or too small. When the thickness t is too large, a distance between a side wall 211 of the plurality of first grooves 210 and a corresponding side wall of the second grooves may be too large, causing the time for etching the side walls of the second grooves until exposing the side walls 211 of the plurality of first grooves 210 covered by the protective layer 310 is too long. During the process of etching the side walls of the second grooves, the side walls of the second grooves may tend to transform to the etching finishing surface etched with a slower etching rate. Therefore, the etching rate of the side walls of the second grooves may be gradually reduced, which further causes the time for etching to expose the side walls 211 of the plurality of first grooves 210 to be extended and affects the efficiency of forming the photoelectric sensor. When the thickness t is too small, the distance between a side wall 211 of the plurality of first grooves 210 and a corresponding side wall of the second grooves may be too small, resulting in the time for etching the side walls of the second grooves until exposing the side walls 211 of the plurality of first grooves 210 covered by the protective layer 310 is too short. That is, before the side walls of the second grooves transform to the etching finishing surface etched with a slower etching rate, the side walls 211 of the plurality of first grooves 210 may be already exposed. Since the side walls of light traps with eight surfaces formed subsequently are formed by the etching finishing surface etched with a slower etching rate, it may be difficult to form light traps with eight surfaces and increase the photosensitive area. The photosensitive performance of the photosensitive sensor may not be improved. Therefore, the thickness t of the protective layer 310 may be set to 15 Å to 100 Å along the direction perpendicular to the side walls 211 of the plurality of first grooves 210.

As shown in FIG. 17, in one embodiment, forming the protective layer 310 on the side walls 211 of the plurality of first grooves 210 may include: forming a protective material layer covering the top and side walls of the mask layer 120 and the bottoms and the side walls of the plurality of first grooves 210.

The protective material layer 300 may be used to form the protective layer 310.

In this embodiment, the protective material layer 300 may be formed using an atomic layer deposition process. The protective material layer 300 formed by the atomic layer deposition process may have good thickness uniformity and good step coverage capability, such that the protective material layer 300 may be able to conformally cover the top and side walls of the mask layer 120 and the bottoms and the side walls of the plurality of first grooves 210, improving the uniformity of the thickness t of the protective layer 310.

As shown in FIG. 18, a portion of the protective material layer 300 at the bottoms of the plurality of first grooves 210 may be removed, and a remaining portion of the protective material layer 300 may be retained as the protective layer 310.

In this embodiment, a dry etching process may be used to remove the portion of the protective material layer 300 at the bottoms of the plurality of first grooves 210.

The dry etching process is an anisotropic etching dry etching process, which may be beneficial to reducing the damage to the substrate 100 at the bottoms of the plurality of first grooves 210 and the protective layer 310 on the side walls of the plurality of first grooves 210.

During the process of forming the protective material layer 300, the top of the mask layer 120 may be more exposed than the bottoms of the plurality of first grooves 210. Therefore, in the actual process, the thickness of the protective material layer 300 on the top of the mask layer 120 may be larger than the thickness of the protective material layer 300 at the bottoms of the plurality of first grooves 210. Therefore, in the process of removing the protective material layer 300 at the bottoms of the plurality of first grooves 210, the protective material layer 300 on the top of the mask layer 120 may not be completely removed. For this reason, in one embodiment, the protective layer 310 may also cover the top of the mask layer 120.

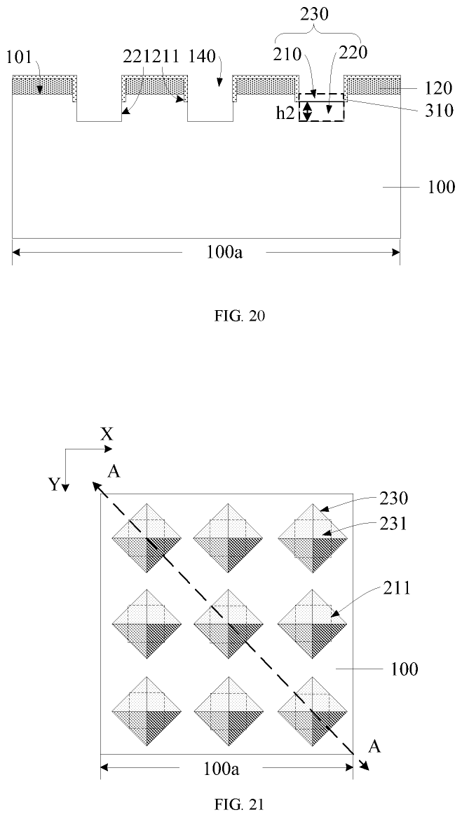

As shown in FIG. 19 which is an enlarged top view of the dot line box in FIG. 15 and FIG. 20 which is a cross-sectional view along the AA direction in FIG. 19, after forming the protective layer 310, a portion of the thickness of the substrate 100 exposed by the plurality of the first grooves 210 may be removed to form second grooves 220 connected to the plurality of first grooves 210. The side walls 221 of the second grooves 220 may be perpendicular to the <100> crystal direction. The plurality of first grooves 210 and the second grooves 220 may form initial light traps 230.

For ease of illustration, the mask layer 120 and the protective layer 310 located on the light-receiving surface 101 are not shown in FIG. 19.

The second grooves 220 may expose planes perpendicular to the <100> crystal direction which are used to provide the planes perpendicular to the <100> crystal direction for the subsequent formation of light traps. In this embodiment, the plurality of first grooves 210 are square grooves, correspondingly the second grooves 220 are also square grooves. The side walls 221 of the second grooves 220 may be the {100} crystal plane, perpendicular to the <100> crystallographic direction. The plurality of first grooves 210 and the second grooves 220 may form initial light traps 230 which are used for subsequent etching of the initial light traps 230 to form light traps.

In this embodiment, a dry etching process may be used to etch a portion of the thickness of the substrate 100 exposed by the plurality of first grooves 210 to form the second grooves 220. The dry etching process is an anisotropic etching dry etching process. Its longitudinal etching rate is much greater than the lateral etching rate, and it may be able to obtain quite accurate pattern conversion along the plurality of first grooves 210 to form the second grooves 220 whose side walls are perpendicular to the <100> crystallographic direction. It may also be beneficial to improving the topography quality and dimensional accuracy of the side walls 221 of the second grooves 220. Further, it may be easy to control the process parameters of the dry etching process, which is beneficial to controlling the thickness of the removed substrate 100 to form the second grooves 220 with a target depth.

The depth h2 of the second grooves 220 should not be too large, nor should it be too small. When the depth h2 of the second grooves 220 is too large, the slope of the upper side walls of the subsequently formed light traps may be too large, making it difficult for the light traps to disperse incident light to multiple angles and to increase the effective optical path of light. Therefore, it may be difficult to trap light. When the depth h2 of the second grooves 220 is too small, it may be difficult for the second grooves 220 to expose a sufficient area of the {100} crystal plane. In the subsequent etching process, by etching the {100} crystal plane, the side walls 221 of the second grooves 220 may transform to the etching completion surface with a slower etching rate. Therefore, the second grooves 220 may have difficulty to expose a sufficient area of the {100} crystal plane, which affects the transformation of the side walls 221 of the second grooves 220 to the etching completion surface with a slower etching rate, making it difficult to form light traps with eight surfaces. Therefore, it may be difficult to obtain a larger photosensitive area and improve the performance of the photoelectric sensor. In this embodiment, the depth h2 of the second grooves 220 may be set to 100 nm to 150 nm.

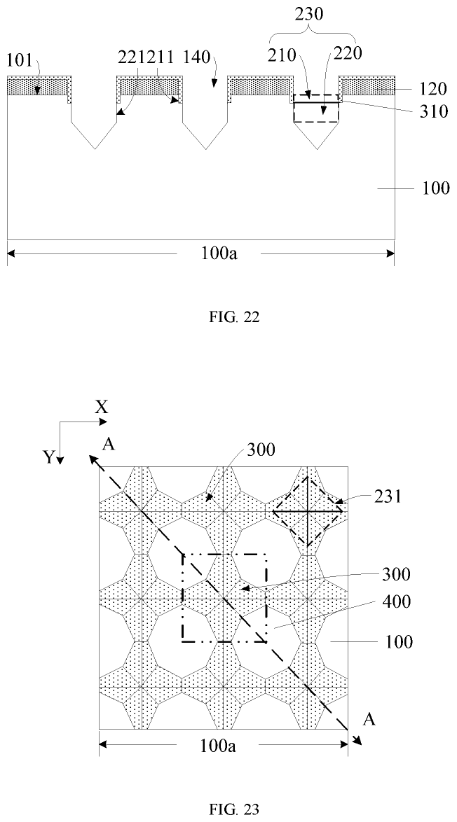

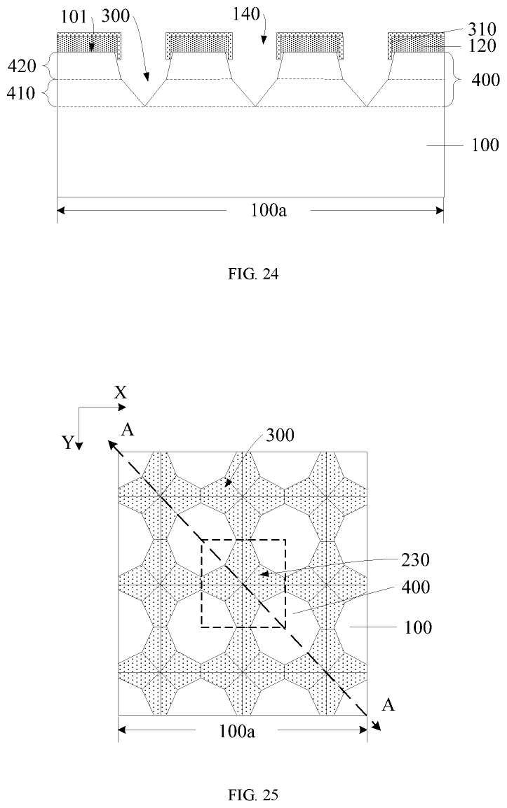

FIG. 21 is a top view based on FIG. 19. The dotted line frame in FIG. 21 is the initial position of the side walls 221 of the second grooves 220. FIG. 22 is a cross-sectional view along the AA direction of FIG. 21. FIG. 23 is a top view of FIG. 21, and FIG. 24 is a cross-sectional view along the AA direction in FIG. 23. As shown in FIG. 21 to FIG. 24, a wet etching process may be used to etch the substrate 100 exposed by the second grooves 220, so that the initial light traps 230 may be connected in the row direction and the column direction respectively, to form light traps 300 and protrusions 400 surrounded/formed by the side walls of the light traps 300. The protrusions 400 may have a shape of an octagonal pyramid. Among the etching rates of various crystal planes of the substrate 100 in the wet etching process, the etching rate of the {100} crystal plane is the largest, and the etching rate of the {111} crystal plane is the smallest.

For simplicity, the mask layer 120 and the protective layer 310 are not shown in FIG. 21 and FIG. 23.

FIG. 21 and FIG. 22 show diagrams where the initial light traps 230 just begin to expose the side walls 211 of the plurality of first grooves 210 after etching the substrate 100 exposed by the second grooves 220 for a period.

The light traps 300 may improve the optical transmittance of the photosensitive pixel areas P and increase the photoelectric conversion efficiency, thereby improving the optical sensitivity performance of the photoelectric sensor.

The plurality of light traps 230 may be disposed above the photoelectric elements, which may slow down the change of the refractive index between the air and the first surface 101 to reduce the high reflectivity caused by the sudden change of the refractive index at the interface. Therefore, more light may be able to enter the photoelectric elements, and the transmittance of the incident light may be improved. Further, by arranging the light traps 230 in the plurality of pixel unit areas 100a of the first surface 101, when the incident light irradiates to the light traps 300 after passing the light-receiving surface 101, the incident light may be dispersed to multiple angles through process including reflection, refraction, or scattering, increasing the effective optical path of light and playing a role in trapping light. The absorption efficiency of the light in the photoelectric elements.

In the present disclosure, the light-receiving surface may be a {100} crystal plane or a {110} crystal plane. Side walls of the first grooves may be perpendicular to the <100> crystal direction, and side walls of the corresponding second grooves may be also perpendicular to the <100> crystal direction. Among the etching rates of each crystal plane in the wet etching process, the etching rate for the {100} crystal plane may be the largest, and the etching rate for the {111} crystal plane may be the smallest. That is, the wet etching process may have the highest etching rate along the <100> crystal direction, and the smallest etching rate along the <111> crystal direction. Since a protective layer may be formed on the side walls of the first grooves, the side walls of the second groove may be etched before the side walls of the first grooves. In the process of etching the substrate exposed by the second grooves, the completed surface obtained by etching may gradually approach the {111} crystal plane, that is, the side walls of the second grooves may gradually become four {111} crystal planes. After the second grooves expose the {111} crystal planes, as the etching continues, the second grooves may expose the side walls of the first grooves. The sidewalls of the first grooves may be perpendicular to the <100> crystallographic direction. Therefore, the etching rate of the substrate at the exposed side walls of the first grooves may be accelerated, while the etching rate of the substrate of the {111} crystal plane exposed by the second grooves may be still slow. Because of the difference in etching rates between the two places, each {111} crystal plane may be etched to form two faces. Correspondingly, the aforementioned four {111} crystal planes may be etched to form totally eight faces. Therefore, after the initial light traps are connected in the row direction and the column direction to form the light traps, the shape of the protrusions surrounded by side walls of the light traps may be an eight-sided pyramid. In a pixel unit area, the eight sides and the top surface of each protrusion may be used as the photosensitive surface of the light sensor. Compared with the light trap with an inverted pyramid structure or a rectangle structure of the photoelectric sensor, the embodiments of the present disclosure may significantly increase the photosensitive area of the photoelectric sensor, and increase the number of reflections of incident light between the photosensitive surfaces. At the same time, the optical path difference of the incident light may be also increased, improving the light localization capability of the photoelectric sensor. The photosensitive performance of the photoelectric sensor may be improved.

As shown in FIG. 21 and FIG. 22, in one embodiment, the dotted line frame in FIG. 21 is the initial position of the side walls 221 of the second grooves 220. During the process of etching the substrate 100 exposed by the side walls 221 of the second grooves 220, the side walls 221 of the second grooves 220 may transform to transition side walls 231, and the transition side walls 231 may be the {111} crystal plane. At this time, the initial light traps 230 may have an inverted pyramid structure. As the etching process continues, the side walls 211 of the plurality of first grooves 210 may contact the etching solution and attend the etching process. The side walls 211 of the plurality of first grooves 210 may be the {100} crystal plane. Therefore, as shown in FIG. 23 and FIG. 24 where the dotted line frame in FIG. 23 is the position of the transition side walls 231, after continuing to etch the initial light traps 230, light traps 300 with eight inclined side walls may be formed. The light traps 300 may be grooves surrounded by eight side walls in the dotted line frame in FIG. 23.

In one embodiment, the etching solution in the wet etching process may include TMAH solution.

The substrate 100 may be made of a material including silicon. The TMAH solution may have the largest etching rate for the {100} crystal plane in the silicon lattice and the smallest etching rate for the {111} crystal plane. Then the difference in etching rates of the TMAH solution on different crystal planes of silicon may be used to form the plurality of protrusions 400 with a shape of an octagonal pyramid.

During wet etching using TMAH solution, the etching time of the wet etching process should not be too long or too short. When the etching time is too long, too much of the substrate 100 may be removed, and the area of the remaining substrate outside the light traps 300 (that is, the protrusion 400) may be too small. The mask layer 120 on the protrusions 400 may fall off and fall into the pickling tank easily during the etching process for forming the plurality of light traps 230, thereby causing the contamination of the pickling tank and affecting other subsequent processes using the pickling tank. When the etching time is too short, the time may be not enough to complete the etching of the side walls 221 of the second grooves 200 to form the transition side walls 231 and the etching of the transition side walls 231 and the side walls 211 of the plurality of first grooves 210 to form the eight sidewalls of the light traps 300, affecting the formation of the photoelectric sensor. Therefore, in the step of wet etching using TMAH solution, the etching time of the wet etching process may be set to 200 s to 300 s.

The number of the light traps 230 may be multiple, thereby increasing the density of the light traps 230 in each pixel unit area 100a. Also, the light traps 230 may be distributed in a matrix along the row direction and the column direction. Adjacent light traps 230 in the row direction may be connected, and adjacent light traps 230 in the column direction may be connected. The optical transmittance may be increased further.

The density of the light traps 230 may be the ratio of the sum of the opening areas of all the light traps 230 in the photosensitive pixel area P to the sum of the areas of the top surfaces of the protrusions 400 in the photosensitive pixel area P.

Correspondingly, the number of protrusions 400 in each pixel unit area 100a may be multiple. The multiple protrusions 400 may be disposed in a matrix along the row direction and the column direction in the pixel unit area 100a.

The height H of the protrusions 400 should not be too large or too small. Since the plurality of light traps 230 and the protrusions 400 are formed by etching part of the thickness of the substrate 100, when the height H of the protrusions 400 is too large, the remaining thickness of the substrate 100 may be too small, that is, the thickness of the base 100 at the bottom of the protrusions 400 may be too small and the photon absorption capacity of the light incident on the bottom of the protrusions 400 may be poor. Especially for incident light with longer wavelengths such as near infrared rays, the light absorption efficiency of the substrate 100 at the bottom of the protrusions 400 may be lower, thereby affecting the light absorption of the photoelectric sensor. When the height H of the protrusions 400 is too small, the height of the plurality of light traps 230 may be too small, and the height of the plurality of initial light traps may be too small. Therefore, the amount of substrate 100 to be etched on the side of the plurality of initial light traps may be too small, resulting in etching the side walls of the initial light trap too quickly, that is, etching the {100} crystal plane to transform into the {111} crystal plane too quickly. After transforming into the {111} crystal plane, the etching rate may decrease. The process time for forming the plurality of light traps 230 may be increased and the process efficiency may be reduced, making it difficult to form the octagonal pyramid profile. Also, when the height H of the protrusions 400 is too small, the slope of the side walls of the protrusions 400 may be too small, that is, the slope of the side walls of the plurality of light traps 230 may be too small. Correspondingly, the number of reflections of the incident light may be too small, making it difficult to increase the optical path difference and difficult to improve the photosensitive performance of the photoelectric sensor. Therefore, in this embodiment, the height H of the protrusions 400 may be set to 300 nm to 400 nm.

When using a wet etching process to etch the substrate 100 exposed by the plurality of initial light traps, a portion of the substrate 100 above the bottom surfaces of the plurality of initial light traps may be etched to form a portion of the plurality of protrusions 400, and another portion of the substrate 100 below the bottom surfaces of the plurality of initial light traps may be etched to form a remaining portion of the plurality of protrusions 400. Therefore, in this embodiment, one protrusion 400 may include a bottom protrusion 410 and a top protrusion 420 located on the bottom protrusion 410. Both the bottom protrusion 410 and the top protrusion 420 may be octagonal pyramids. The bottom surface of the top protrusion 420 and the top surface of the bottom protrusion 410 may coincide.

Further, when forming the plurality of initial light traps, an etching mask may be used to protect the areas that do not need to be etched. That is, the etching mask may be formed on the substrate 100 outside the plurality of initial light traps. During the wet etching process, the top of the portion of the substrate 100 above the bottom surfaces of the plurality of initial light traps may be etched more slowly, and the amount of etching solution in contact with the top may be small. Therefore, the etched amount of the portion of the substrate 100 above the bottom surfaces of the plurality of initial light traps may be smaller. The portion of the substrate 100 below the bottom surfaces of the plurality of initial light traps may be etched more quickly, and the amount of etching solution in contact with the portion of the substrate 100 below the bottom surfaces of the plurality of initial light traps may be larger. Therefore, the etched amount of the portion of the substrate 100 below the bottom surfaces of the plurality of initial light traps may be larger. Correspondingly, in this embodiment, the slope of the side wall of the bottom protrusion 410 may be larger than the slope of the side wall of the top protrusion 420.

Correspondingly, in this embodiment, the height h of the top protrusion 420 may be 100 nm to 150 nm.

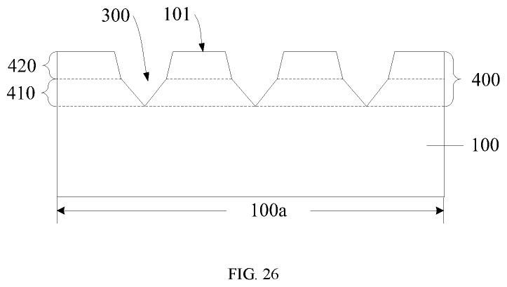

FIG. 25 is a top view based on FIG. 23. The dotted frame in FIG. 25 is used to represent the light traps 300. FIG. 26 is a cross-sectional view based on the AA direction of FIG. 25. As shown in FIG. 25 and FIG. 26, in one embodiment, after the protrusions 400 are formed, the method may further include removing the mask layer 120 and the protective layer 310.

The mask layer 120 and the protective layer 310 may be removed to expose the light-receiving surface 101 to provide a platform for subsequent processes.

In this embodiment, a wet etching process is used to remove the mask layer 120 and the protective layer 310. The wet etching process has the characteristics of isotropic etching, which is beneficial to removing the mask layer 120 and the protective layer 310. The cost of the wet etching process is relatively low, and the operation steps are simple. Also, a larger etching selectivity ratio may be achieved, which is beneficial to reducing damage to the substrate 100 during the process of removing the mask layer 120 and the protective layer 310.

Subsequently, a dielectric structure layer (not shown) may also be formed. The dielectric layer may include a conformal dielectric layer (not shown) formed on the surface of the light traps 300 and the top surface of the protrusions 400; and a light-transmitting layer (not shown), located on the conformal dielectric layer in the light traps 230 and filled in the light traps 230.

The specific description of forming the dielectric structure layer will not be described again here.

The present disclosure also provides an electronic device, including any photoelectric sensor provided by various embodiments of the present disclosure.

The electronic device in the present disclosure may be a mobile phone, a tablet computer, a laptop, a navigator, a camera, a video camera, a sweeping robot, a virtual reality device, an augmented reality device, or any other electronic product or device with a photoelectric sensing function, or any intermediate product including the aforementioned photoelectric sensor.

In the present disclosure, the photosensitive area of the photoelectric sensor may be significantly increased, and the number of reflections of incident light between the photosensitive surfaces may be also increased. At the same time, the optical path difference of the incident light may be also increased. The light localization capability of the photoelectric sensor may be improved, therefore improving the photosensitive performance of the photoelectric sensor. By using the photoelectric sensor provided by the embodiments of the present disclosure, the performance of the electronic device and the user's experience may be improved.

The embodiments disclosed herein are exemplary only. Other applications, advantages, alternations, modifications, or equivalents to the disclosed embodiments are obvious to those skilled in the art and are intended to be encompassed within the scope of the present disclosure.

1. A photoelectric sensor, comprising:
a substrate, wherein the substrate has a light-receiving surface, and the substrate includes a photosensitive pixel area and the photosensitive pixel area includes a plurality of pixel unit areas distributed in a matrix; and
a plurality of light traps located in a part of a thickness of the substrate in the plurality of pixel unit area, wherein: the plurality of light traps is on the light-receiving surface of the substrate, the plurality of light traps is distributed in a matrix along a row direction and a column direction, the row direction and the column direction are perpendicular, adjacent light traps in the column direction are connected, adjacent light traps in the row direction are connected, side walls of the plurality of light traps surround and form a plurality of protrusions, adjacent protrusions are connected, and the plurality of protrusions has a shape of octagonal pyramid.

2. The photoelectric sensor according to claim 1, wherein:
a shape of a top surface of one protrusion of the plurality of protrusions is an octagon;
along an extension direction of a longest diagonal in the octagon, a diagonal length of the top surface of the protrusion is a first length;
the first length is about 250 nm to about 350 nm;
along the extension direction of the longest diagonal, among adjacent protrusion, an extension direction of a line connecting opposite vertices of the adjacent protrusion coincides with the extending direction of the longest diagonal;
a distance between the opposite vertices of the adjacent protrusion is a second length;
the second length is about 250 nm to about 350 nm; and
the extending direction of the longest diagonal has included angles with the row direction and the column directions respectively.

3. The photoelectric sensor according to claim 2, wherein:
the first length is equal to the second length.

4. The photoelectric sensor according to claim 1, wherein:
a height of the plurality of protrusions is about 300 nm to about 400 nm.

5. The photoelectric sensor according to claim 1, wherein:
one protrusion of the plurality of protrusions includes a bottom protrusion and a top protrusion located on the bottom protrusion,
both the bottom protrusion and the top protrusion are octagonal pyramids;
a bottom surface of the top protrusion and a top surface of the bottom protrusion are overlapping; and
a slope of side walls of the bottom protrusion is larger than a slope of side walls of the top protrusion.

6. The photoelectric sensor according to claim 5, wherein:
a height of the top protrusion is about 100 nm to about 150 nm.

7. The photoelectric sensor according to claim 1, wherein:
a shape of a top surface of one protrusion of the plurality of protrusions is an octagon, and a side length of the octagon is about 100 nm to about 150 nm.

8. The photoelectric sensor according to claim 1, wherein:
a shape of a bottom surface of one protrusion of the plurality of protrusions is an octagon, and a side length of the octagon is about 200 nm to about 300 nm.

9. The photoelectric sensor according to claim 1, wherein:
the substrate has a cubic crystal structure;
a material lattice of the substrate includes a {100} crystal plane family, a {110} crystal plane family and a {111} crystal plane family; and
a top surface of the substrate is the {100} crystal plane or the {110} crystal plane.

10. The photoelectric sensor according to claim 1, wherein:
the substrate is made of a material including silicon, and the plurality of protrusions is made a material including silicon.

11. A fabrication method of a photoelectric sensor, comprising:
providing a substrate, wherein the substrate includes a photosensitive pixel area and the photosensitive pixel area includes a plurality of pixel unit areas distributed in a matrix; the substrate has a cubic crystal structure; a material lattice of the substrate includes a {100} crystal plane family, a {110} crystal plane family and a {111} crystal plane family; and a light-receiving surface of the substrate is the {100} crystal plane or the {110} crystal plane;
forming a plurality of discrete first grooves in the light-receiving surface of the substrate in the plurality of pixel unit areas, wherein: the plurality of first grooves is square grooves or circular grooves; side walls of plurality of first grooves are perpendicular to the <100> crystal direction, the plurality of first grooves is arranged in a matrix along a row direction and a column direction; and the row direction and the column direction are perpendicular;
forming a protective layer on the side walls of the plurality of first grooves;
after forming the protective layer, removing a portion of a thickness of the substrate exposed by the plurality of first grooves, to form second grooves connected to the plurality of first grooves, wherein: side walls of the second grooves are perpendicular to the <100> crystal direction, and the plurality of first grooves and the second grooves form initial light traps; and
using a wet etching process to etch the substrate exposed by the second grooves, such that the initial light traps are connected along the row direction and the column direction respectively to form light traps and protrusions surrounded by side walls of the light traps, wherein: adjacent protrusions are connected; the plurality of protrusions has a shape of an octagonal pyramid; and among the etching rates of the various crystal planes of the substrate in the wet etching process, the etching rate of the {100} crystal plane is the largest, and the etching rate of the {111} crystal plane is the smallest.

12. The fabrication method of the photoelectric sensor according to claim 11, before forming the plurality of discrete first grooves in the light-receiving surface of the substrate in the plurality of pixel unit areas, further including:
forming a mask layer on the substrate; and
patterning the mask layer to form first openings in the mask layer, wherein the first openings are square openings or circular openings;
wherein:
forming the plurality of discrete first grooves in the light-receiving surface of the substrate in the plurality of pixel unit areas includes using the mask layer as a mask to remove a portion of the thickness of the substrate exposed by the first openings.

13. The fabrication method of the photoelectric sensor according to claim 12, wherein:
patterning the mask layer includes:
forming photoresist on the mask layer, wherein second openings are formed in the photoresist and the second openings are square openings or circular openings; and
removing a portion of the mask layer exposed by the second openings to form the first openings in the mask layer,
and
after forming the plurality of first grooves, the method further includes: removing the photoresist.

14. The fabrication method of the photoelectric sensor according to claim 12, wherein:
forming the protective layer on the side walls of the plurality of first grooves includes:
forming a protective material layer covering a top and side walls of the mask layer, and bottoms and side walls of the plurality of first grooves; and
removing a portion of the protective material layer on the bottoms of the plurality of first grooves, to use a remaining portion of the protective material layer as the protective layer.

15. The fabrication method of the photoelectric sensor according to claim 14, wherein:
when forming the protective material layer, an atomic layer deposition process is used to form the protective material layer.

16. The fabrication method of the photoelectric sensor according to claim 11, wherein:
when forming the plurality of discrete first grooves in the light-receiving surface of the substrate, the plurality of first grooves are square grooves.

17. The fabrication method of the photoelectric sensor according to claim 11, wherein:
when forming the plurality of discrete first grooves, a dry etching process is used to form the plurality of discrete first grooves.

18. The fabrication method of the photoelectric sensor according to claim 11, wherein:
when forming the second grooves connected to the plurality of first grooves, a dry etching process is used to remove the portion of the thickness of the substrate exposed by the plurality of first grooves, to form the second grooves.

19. The fabrication method of the photoelectric sensor according to claim 11, wherein:
when using the wet etching process to etch the substrate exposed by the second grooves, the wet etching process uses an etching solution including TMAH solution.

20. (canceled)

21. (canceled)

22. (canceled)

23. (canceled)

24. (canceled)

25. (canceled)

26. (canceled)

27. (canceled)

28. (canceled)

29. (canceled)

30. An electronic device, including a photoelectric sensor wherein,
the photoelectric sensor includes:
a substrate, wherein the substrate has a light-receiving surface, and the substrate includes a photosensitive pixel area and the photosensitive pixel area includes a plurality of pixel unit areas distributed in a matrix; and
a plurality of light traps located in a part of a thickness of the substrate in the plurality of pixel unit area, wherein: the plurality of light traps is on the light-receiving surface of the substrate, the plurality of light traps is distributed in a matrix along a row direction and a column direction, the row direction and the column direction are perpendicular, adjacent light traps in the column direction are connected, adjacent light traps in the row direction are connected, side walls of the plurality of light traps surround and form a plurality of protrusions, adjacent protrusions are connected, and the plurality of protrusions has a shape of octagonal pyramid.
